(19) United States
(12) Patent Application Publication
(10) Pub. No.: US 2017/0221730 A1
(43) Pub. Date: Aug. 3, 2017

(54) SUBSTRATE PROCESSING HEATER DEVICE AND SUBSTRATE SOLUTION PROCESSING DEVICE HAVING SAME

(71) Applicant: ZEUS CO., LTD., Osan-si, Gyeonggi-do (KR)

(72) Inventors: Kwang Il JUNG, Yongin-si (KR); Byeong Su LEE, Osan-si (KR); Joo Hyung RYU, Seoul (KR)

(73) Assignee: ZEUS CO., LTD., Yongin-si, Gyeonggi-do (KR)

(21) Appl. No.: 15/328,595

(22) PCT Filed: Aug. 28, 2015
(86) PCT No.: PCT/KR2015/009051

§ 371 Date: Jan. 24, 2017

(30) Foreign Application Priority Data
Oct. 10, 2014 (KR) 10-2014-0136938
Oct. 10, 2014 (KR) 10-2014-0136939

(51) Int. Cl. H01L 21/67; H01L 21/68

(52) U.S. Cl. CPC H01L 21/67023; H01L 21/67248; H01L 21/68; H01L 21/67115; H01L 21/67075

(57) ABSTRACT

The present invention relates to a substrate processing heater device that heats a substrate to process the substrate and a substrate solution processing device including the same. The substrate processing heater device includes a heater part having an opposite surface with a size greater than that of a processing surface of the substrate to heat the substrate and a lamp part comprising a plurality of lamp units disposed adjacent to each other on the heater part. Thus, since the opposite surface of the heater part has the size greater than that of the processing surface of the substrate, and the plurality of lamp units are disposed adjacent to each other, a heating temperature may be uniformly maintained on the processing surface of the substrate to prevent the substrate processing surface from being non-uniformly processed, thereby improving substrate processing efficiency.

### TECHNICAL FIELD

The present invention relates to a substrate processing heater device and a substrate solution processing device having the same, and more particularly, to a substrate processing heater device that heats a substrate to process the substrate and measures a temperature of the substrate and a substrate solution processing device having the same.

### BACKGROUND ART

In order to manufacture semiconductor devices, it is necessary to perform etching and cleaning processes in forming of multilayered thin films on a substrate.

A substrate solution processing device such as single wafer type wet etching and cleaning devices supplies a processing solution to a substrate to perform etching, cleaning, and drying processes while rotating a table on which a chuck supporting the substrate and collect the processing solution by using a processing solution collection part having a cup structure around the table.

When the thin films such as a nitride film, an oxide film, a metal film, and the like, which are deposited on the substrate, or photoresist is removed from the substrate, the solution is processed at a high temperature through a method, in which a heater is installed above the substrate or in a lower portion of the table, the processing solution is heated at a high temperature and then injected, or reaction heat generated by mixing the processing solution just before injecting the processing solution after heating the processing solution is used, with the purpose of improving processing efficiency.

Particularly, in the heater type substrate solution processing device using the heater device according to related art, since the heater has a size less than that of a processing surface of the substrate, the processing surface of the substrate may be non-uniformly heated to cause processing defects when the substrate is processed by using the processing solution.

Also, when the heaters are disposed in a fixed arrangement with respect to the processing surface of the substrate, heating ranges of the heater may equally overlap each other or repeatedly overlap each other in a triplex-duplex shape to cause non-uniformity in heating temperature of the processing surface of the substrate.

Also, to solve the problem in which the heating temperature with respect to the processing surface of the substrate is non-uniform, the heater has to be controlled in intensity. However, it is not easy to detect a portion at which the heating temperature of the substrate is non-uniform, and also, it is difficult to control the intensity of the heater.

### DISCLOSURE OF THE INVENTION

### Technical Problem

To solve the above-mentioned problems according to the related art, an object of the present invention is to provide a substrate processing heater device which is capable of uniformly maintaining a heating temperature on a substrate processing surface and preventing the substrate processing surface from being non-uniformly processed to improving processing efficiency of the substrate and a substrate solution processing device having the same.

Also, another object of the present invention is to provide a substrate processing heater device which is capable of concentrating the intensity of a heater part into a processing surface to improve heating efficiency of the heater part and a substrate solution processing device having the same.

Also, further another object of the present invention is to provide a substrate processing heater device which is capable of disposing lamp units so that heating ranges of the lamp units do not overlap each other to reduce non-uniformity of a heating temperature on a substrate processing surface and a substrate solution processing device having the same.

Also, further another object of the present invention is to provide a substrate processing heater device which is capable of preventing a heating temperature from being risen at a central portion of a substrate processing surface and a substrate solution processing device having the same.

Also, further another object of the present invention is to provide a substrate processing heater device which is capable of reflecting heat energy of a heating lamp emitting high-temperature heat energy toward a substrate to improve heat energy efficiency and preventing a housing from being thermally damaged and a substrate solution processing device having the same.

Also, further another object of the present invention is to provide a substrate processing heater device which is capable of uniformly emitting heat energy of a heating lamp and easily maintaining and repairing lamp units and a substrate solution processing device having the same.

Also, further another object of the present invention is to provide a substrate processing heater device which is capable of controlling intensities of lamp units, which are disposed on an opposite surface, for each area and a substrate solution processing device having the same.

Also, further another object of the present invention is to provide a substrate processing heater device which is capable of variously controlling intensities of lamp units with respect to a central portion and an outer portion of a substrate processing surface to reduce a deviation in heating temperature for each area of the substrate processing surface and a substrate solution processing device having the same.

Also, further another object of the present invention is to provide a substrate processing heater device which is capable of measuring a portion at which a heating temperature on a substrate processing surface is non-uniform to provide heating temperature information of the substrate so that a substrate is uniformly heated and thereby to improve substrate processing efficiency and a substrate solution processing device having the same.

Also, further another object of the present invention is to provide a substrate processing heater device in which the temperature measurement part is fixedly installed on the heater part so as to be moved or fixed together with the heater part to simplify a mechanical constitution without installing a separate moving unit or fixing unit for a temperature measurement part and a substrate solution processing device having the same.

Also, further another object of the present invention is to provide a substrate processing heater device which is capable of parallely maintaining a distance between a temperature measurement part and a substrate processing surface to improve accuracy in temperature measurement of a temperature sensor and a substrate solution processing device having the same.

Also, further another object of the present invention is to provide a substrate processing heater device which is capable of easily measuring a temperature of a substrate processing surface along a circumferential direction on a substrate rotated when the substrate is processed and a substrate solution processing device having the same.

Also, further another object of the present invention is to provide a substrate processing heater device which is capable of controlling a heater part so that an intensity of the heater part with respect to the lamp units is uniformly maintained on a substrate processing surface and a substrate solution processing device having the same.

Also, further another object of the present invention is to provide a substrate processing heater device which is capable of concentrating the intensity of a heater part into a processing surface to improve heating efficiency of the heater part and a substrate solution processing device having the same.

Also, further another object of the present invention is to provide a substrate processing heater device which is capable of uniformly emitting heat energy of a heating lamp and easily maintaining and repairing lamp units and a substrate solution processing device having the same.

Also, further another object of the present invention is to provide a substrate processing heater device which is capable of displaying lamp units so that heating ranges of the lamp units do not overlap each other to reduce non-uniformity of a heating temperature on a substrate processing surface and a substrate solution processing device having the same.

Also, further another object of the present invention is to provide a substrate processing heater device which is capable of preventing a heater device from being contaminated when a substrate is processed by using a processing solution and improving solution processing efficiency and a substrate solution processing device having the same.

Also, further another object of the present invention is to provide a substrate processing heater device which is capable of more accurately controlling a heating temperature for each lamp group of lamp units with respect to a substrate processing surface and a substrate solution processing device having the same.

### Technical Solution

To achieve the above-mentioned objects, a substrate processing heater device, which heats a substrate to process the substrate, includes: a heater part heating the substrate; and a lamp part including a plurality of lamp units disposed adjacent to each other on the heater part.

The heater part may have an opposite surface having a size greater than that of a processing surface of the substrate. The opposite surface may have the same shape as the processing surface of the substrate.

The lamp part may include: a reference lamp unit eccentrically disposed with respect to a center of the opposite surface, which corresponds to a center of the processing surface of the substrate; and a plurality of peripheral lamp units disposed at the same spaced distance from a center of the opposite surface or difference spaced distances from the center of the opposite surface by using the reference lamp unit as a center. An eccentric range of the reference lamp unit is within ⅔ of a diameter of each of the lamp units.

Each of the lamp units may include: a heating lamp emitting heat energy toward the substrate; a reflector reflecting the heat energy of the heating lamp to the substrate; and a housing installed on an outer circumference of the heating lamp.

The heating lamp may include a filament disposed parallel to the processing surface of the substrate. The lamp unit may be coupled to be fitted so that the filaments of the heating lamps are disposed in the same direction as each other or directions different from each other. The heating lamp may include an infrared lamp.

The lamp part may include a plurality of lamp groups in which at least one lamp unit constitutes one lamp group, and intensities of the lamp units may be controlled from each lamp group.

One lamp unit may constitute one lamp group at a central portion of the lamp part, and a plurality of lamp units may constitute one lamp group at an outer portion of the lamp part.

Also, the substrate processing heater device may further include a temperature measurement part that measures a temperature of the substrate heated by the heater part in a non-contact manner. The temperature measurement part may be installed on the opposite surface of the heater part, which corresponds to the processing surface of the substrate.

The temperature measurement part may include at least one temperature sensor installed to measure the temperature at a position of the substrate in a vertical direction. The temperature sensor may be provided in plurality along a radius of the opposite surface of the heater part corresponding to the processing surface of the substrate.

Since a plurality of lamp groups in which at least one lamp unit disposed on the opposite surface constitutes one lamp group are provided, and a plurality of control groups in which the plurality of lamp groups constitute one control group are provided, measured results of the temperature sensor may be provided by allowing the temperature sensor to be interlocked with each of the non-contact type sensors and thereby to control intensities of the lamp units for each control group. The temperature sensor may include a non-contact type infrared radiation thermometer.

A substrate solution processing device, which supplies a processing solution to a substrate to process the substrate by using the processing solution, includes: a table part chucking and rotating the substrate; an injection part injecting the processing solution onto the substrate; a collection part collecting the processing solution injected onto the substrate; a heater part heating the substrate; and a lamp part including a plurality of lamp units disposed adjacent to each other on the heater part. The heater part may have an opposite surface having a size greater than that of a processing surface of the substrate.

The table part may chuck the substrate to allow the processing surface of the substrate to face an upper side, the injection part may be installed above the substrate to inject the processing solution onto the processing surface of the substrate, and the heater part may be installed above the substrate to heat the substrate and the processing solution.

The table part may chuck the substrate to allow the processing surface of the substrate to face a lower side, the injection part may be installed below the substrate to inject the processing solution onto the processing surface of the substrate, and the heater part may be installed above the substrate to heat the substrate and the processing solution.

The substrate solution processing device may further include a temperature measurement part that measures a heating temperature of the substrate to control an intensity of the lamp part. The temperature measurement part may measure a temperature of the substrate heated by the heater part in a non-contact manner.

The substrate solution processing device may further include a control part that controls an intensity of the lamp part for each lamp group of the lamp units. Since a plurality of lamp groups in which at least one lamp unit disposed on the opposite surface corresponding to the processing surface of the substrate constitutes one lamp group are provided, and a plurality of control groups in which the plurality of lamp groups constitute one control group are provided, the control part may be interlocked with each of the non-contact type sensors to control intensities of the lamp units for each control group.

### Advantageous Effects

As described above, according to the present invention, since the opposite surface of the heater part has a size greater than that of the substrate processing surface, and the plurality of lamp units are disposed adjacent to each other on the opposite surface, the heating temperature may be uniformly maintained on the substrate processing surface to prevent the substrate processing surface from being non-uniformly processed, thereby improving the substrate processing efficiency.

Also, since the opposite surface of the heater part has the same shape as the substrate processing surface, the intensity of the heater part may be concentrated into only the substrate processing surface to improve the heating efficiency of the heater part.

Also, since the reference lamp unit is eccentrically disposed with respect to the center of the opposite surface, and the peripheral lamp units are disposed to have different spaced distances from the center of the opposite surface, the lamp units may be disposed so that the heating ranges of the lamp units do not overlap each other to reduce the non-uniformity in heating temperature of the substrate processing surface.

Also, the eccentric range of the reference lamp unit may be limited to a predetermined value to prevent the heating temperature from being risen at the central portion of the substrate processing surface.

Also, since each of the lamp units is constituted by the heating lamp, the reflector, and the housing, the heat energy of the heating lamp emitting the high-temperature heat energy may be reflected toward the substrate to improve the heat energy efficiency and prevent the housing from being thermally damaged.

Also, since the filaments as the heating lamps are installed parallel to the substrate processing surface in the same direction or in directions different from each other, and the infrared lamp is used, the heat energy of the heating lamps may be uniformly emitted, and the lamp units may be easily maintained and repaired.

Also, since the plurality of lamp groups in which at least one lamp unit is formed as one lamp group are controlled intensity for each lamp group, the intensities of the lamp units disposed on the opposite surface may be controlled for each area.

Also, since one lamp unit is formed as one lamp group at the central portion of the substrate, and the plurality lamp units are formed as one lamp group at the outer portion, the intensities of the lamp units may be variously controlled at the central portion and the outer portion of the substrate processing surface to reduce the deviation in heating temperature for each area of the substrate processing surface.

Also, since the temperature measurement part is installed so that the temperature of the substrate heated by the heating unit is measured in a non-contact manner, the portion at which the heating temperature on the substrate processing surface is non-uniform may be measured to provide the heating temperature information so that the heating temperature of the substrate is uniformly maintained, thereby improving the substrate processing efficiency.

Also, since the temperature measurement part is installed on the opposite surface of the heater part, the temperature measurement part may be fixedly installed on the heater part so as to be moved or fixed together with the heater part to simplify a mechanical constitution without installing a separate moving unit or fixing unit for a temperature measurement part.

Also, since the temperature measurement part is provided as at least one temperature sensor installed to measure the temperature at a position of the substrate in the vertical direction with respect to the substrate processing surface, the distance between the temperature measurement part and the substrate processing surface may be parallely maintained to improve the accuracy in temperature measurement of the temperature sensor.

Also, since the plurality of temperature sensors are disposed on the opposite surface of the heater part in the radius direction, the temperature of the substrate processing surface rotated when the substrate is processed may be measured along the circumferential direction to easily measure the temperature of the entire substrate processing surface.

Also, since the intensities of the lamp units are controlled for each control group by the measured result of the temperature sensor of the temperature measurement part, the intensity of the heater part with respect to the lamp units may be controlled to be uniformly maintained on the substrate processing surface.

Also, since the opposite surface of the heater part has the same shape as the substrate processing surface, the intensity of the heater part may be concentrated into only the substrate processing surface to improve the heating efficiency of the heater part.

Also, since the filaments as the heating lamps are installed parallel to the substrate processing surface in the same direction, the heat energy of the heating lamps may be uniformly emitted, and the lamp units may be easily maintained and repaired.

Also, since the reference lamp unit is eccentrically disposed with respect to the center of the opposite surface, and the peripheral lamp units are disposed to have different spaced distances from the center of the opposite surface, the lamp units may be disposed so that the heating ranges of the lamp units do not overlap each other to reduce the non-uniformity in heating temperature of the substrate processing surface.

Also, since the heater device is installed above the substrate, and the injection part is installed under the substrate in the substrate solution processing device, when the substrate is processed by using the processing solution, the contamination of the heater device may be prevented, and the solution processing efficiency may be improved.

Also, since the temperature measurement part and the control part are provided in the substrate solution processing device, the heating temperature with respect to the substrate processing surface may be more accurately controlled for each lamp group of the lamp units.

### BRIEF DESCRIPTION OF THE DRAWINGS

FIG. 1 is a view of a substrate solution processing device including a substrate processing heater device according to a first embodiment of the present invention.

FIG. 2 is a view of the substrate processing heater device according to the first embodiment of the present invention.

FIG. 3 is a detailed view of a heater unit of the substrate processing heater device according to the first embodiment of the present invention.

FIG. 4 is a block diagram illustrating a control state of the substrate processing heater device according to the first embodiment of the present invention.

FIG. 5 is a view of a substrate solution processing device including a substrate processing heater device according to a second embodiment of the present invention.

FIG. 6 is a view of the substrate processing heater device according to the second embodiment of the present invention.

FIG. 7 is a view illustrating an arrangement of a control group of the substrate processing heater device according to the second embodiment of the present invention.

FIG. 8 is a block diagram illustrating a control state of the substrate processing heater device according to the second embodiment of the present invention.

### DESCRIPTION OF THE CODE ON THE MAIN PART OF THE DRAWING

| | |
|---|---|
| 10: Heater part | 20: Lamp part |
| 30: Temperature measurement part | 40: Control part |
| 110: Table part | 120: Injection part |
| 130: Collection part | |

### MODE FOR CARRYING OUT THE INVENTION

Hereinafter, a substrate processing heater device according to a preferred first embodiment of the present invention will be described in more detail with reference to the accompanying drawings.

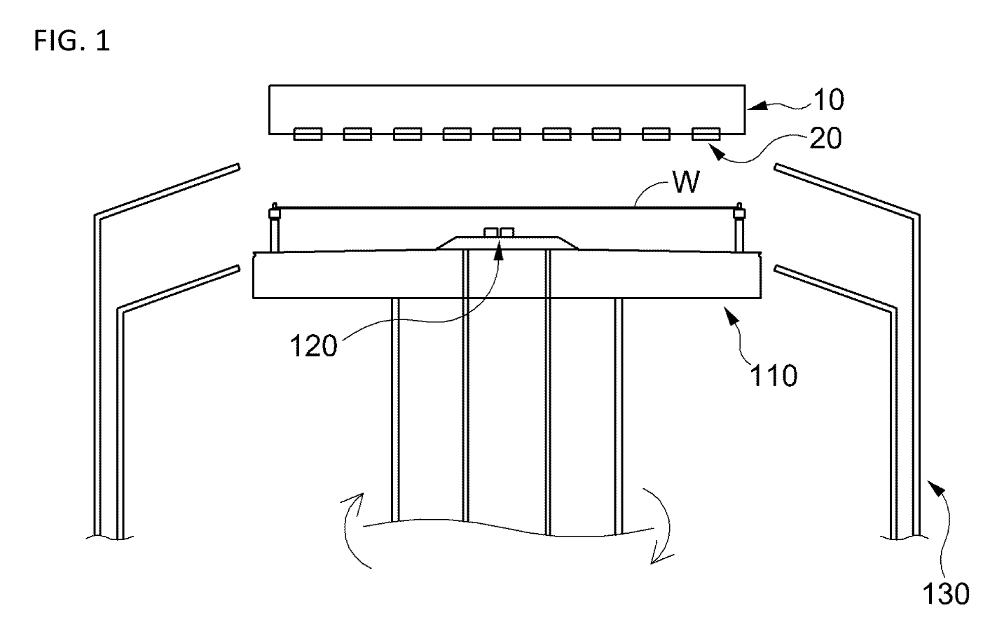

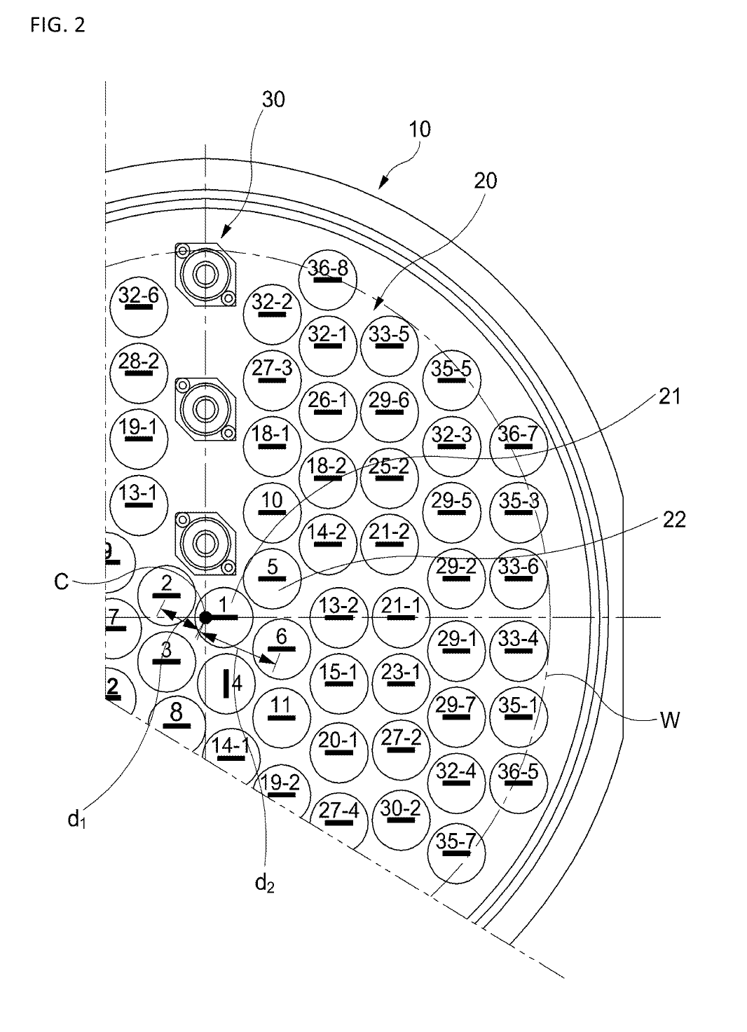

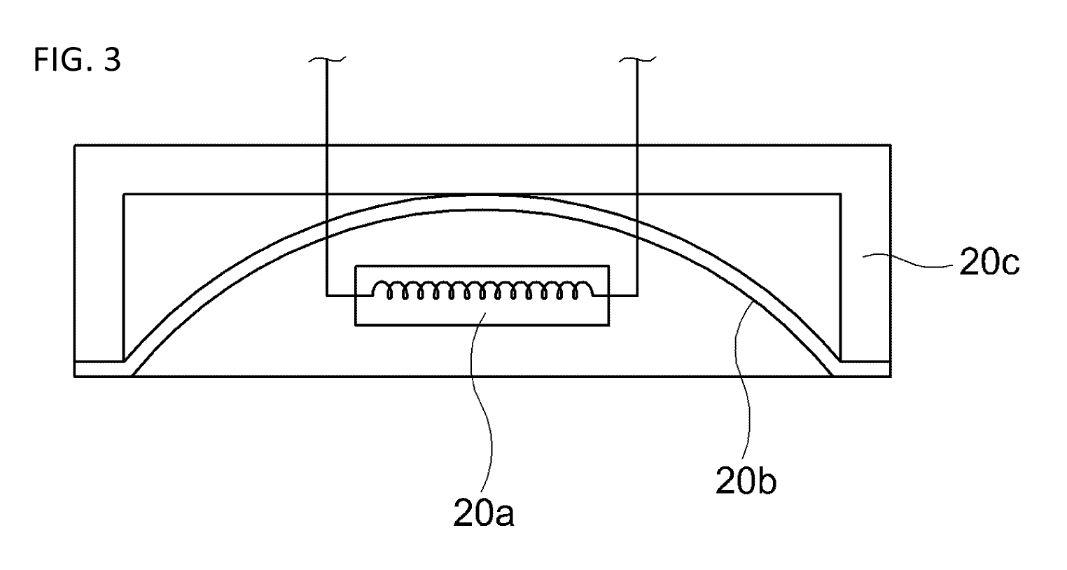

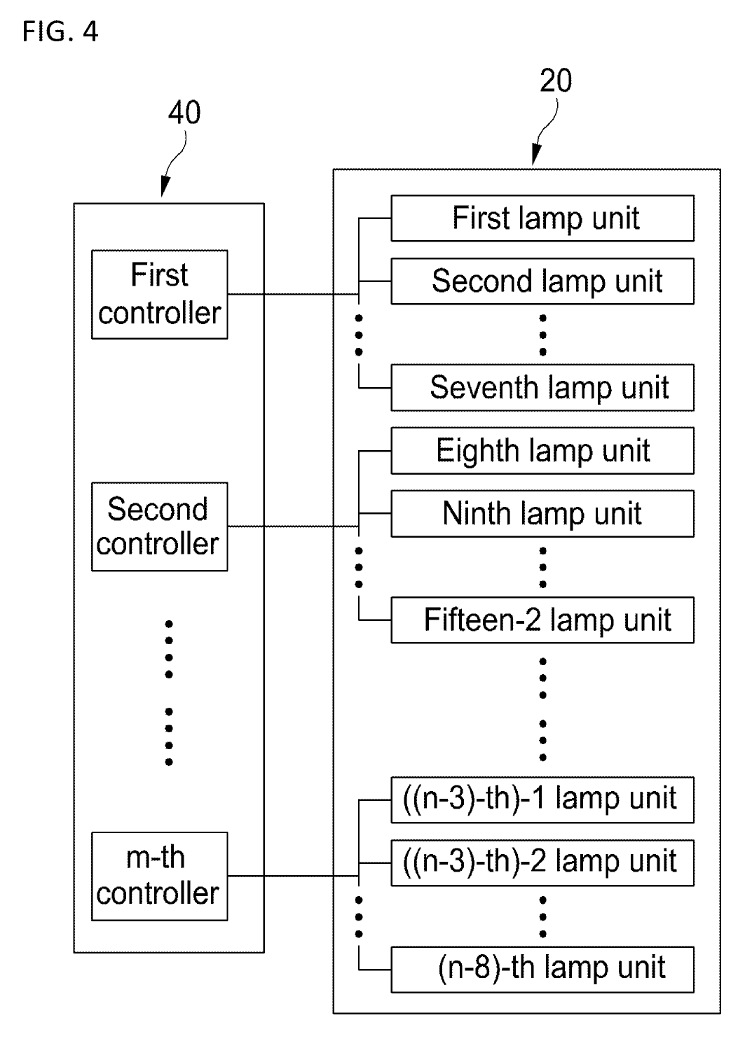

FIG. 1 is a view of a substrate solution processing device including a substrate processing heater device according to a first embodiment of the present invention, FIG. 2 is a view of the substrate processing heater device according to the first embodiment of the present invention, FIG. 3 is a detailed view of a heater unit of the substrate processing heater device according to the first embodiment of the present invention, and FIG. 4 is a block diagram illustrating a control state of the substrate processing heater device according to the first embodiment of the present invention.

As illustrated in FIGS. 1 and 2, the substrate processing heater device according to the first embodiment includes a heater part 10 and a lamp part 20 and is a heater device for heating a substrate to process the substrate. Preferably, a circular thin plate such as a semiconductor wafer used for a semiconductor device may be used as the substrate processed in the current embodiment.

The heater part 10 may be a heating unit that has an opposite surface having a size greater than that of a processing surface of a substrate W to heat the substrate W. Preferably, the heater part 10 may have the same shape as the processing surface of the substrate W.

Particularly, when the processing surface of the substrate W has a circular shape, the heater part 10 may have a circular shape having an opposite surface that has a size greater than that of the circular shape of the substrate W.

The heater part 10 may be installed so that the heater part 10 is rotated above the substrate W to enter or fixed above the substrate W. Thus, when the processing surface of the substrate W is installed to be faced downward, a back surface of the substrate W is heated. When the processing surface of the substrate W is installed to be faced upward, the processing surface of the substrate W is heated.

The lamp part 20 may be a heating unit including a plurality of lamp units disposed adjacent to each other on the opposite surface of the heater part 10 to emit heat energy toward the processing surface of the substrate W. The lamp part 20 includes a reference lamp unit 21 and peripheral lamp units 22.

The reference lamp unit 21 may be eccentrically disposed with respect to a center of the opposite surface corresponding to a center of the processing surface of the substrate W. Particularly, the eccentric range of the reference lamp unit 21, i.e., a spaced distance between the center of the opposite surface and the center of the reference lamp unit 21 may be set within ⅔ of a diameter of each of the lamp units. The reason is because heating performance with respect to the central portion of the substrate processing surface is deteriorated to non-uniformly heat the substrate processing surface when the eccentric range is less than % of a diameter of each of the lamp units.

The peripheral lamp units 22 are disposed in plurality at the same spaced distance from the center C of the opposite surface or at different spaced distances from the center C of the opposite surface by using the reference lamp unit 21 as a center.

Particularly, like as a spaced distance d1 of a second lamp unit that is marked with reference numeral 2 and a spaced distance d2 of a sixth lamp unit that is marked with reference numeral 6 are different from each other, spaced distances of the plurality of peripheral lamp units are different from each other. Also, portions of the peripheral lamp units may be disposed at the same spaced distance from the center C of the opposite surface.

Thus, since the peripheral lamp units 22 are disposed on the opposite surface of the heater part 10 so that the peripheral lamp units 22 that are marked with reference numerals 1 to n-8 are disposed at spaced distances from each other, the processing surface of the substrate W may be uniformly heated by the lamp units at various points at which the spaced distances from the center C of the opposite surface corresponding to the substrate processing surface are different from each other.

Also, the lamp units 20 includes a plurality of lamp groups in which at least one lamp unit forms one lamp group. Here, the lamp units may be controlled in intensity for each lamp group. Particularly, n lamp groups including first to (n-8)-th lamp units may be provided, and the lamp units may be controlled in intensity for each lamp group.

Also, one lamp unit may be formed as one lamp group at the central portion of the opposite, and the plurality of lamp units may be formed as one lamp group at the outer portion of the opposite surface.

Particularly, in the first to twelve lamp units that are marked with reference numerals 1 to 12 at the central portion of the opposite surface, one lamp unit may be formed as one lamp group, and the lamp units may be controlled in intensity for each lamp group.

Also, in the thirteen-1 to (n-8)-th lamp units that disposed on the outer portion of the opposite surface and are marked with reference numerals 13-1 to n-8, the plurality of lamp units may be formed as one lamp group, and the lamp units may be controlled in intensity for each lamp group.

Also, as illustrated in FIG. 3, each of the lamp units of the lamp part 20 includes a heating lamp 20a, a reflector 20b, and a housing 20c. A lamp socket is disposed on the housing 20c so that the heating lamp 20a is coupled to be fitted.

The heating lamp 20a is a lamp unit that is installed on the opposite surface of the heater part 10 to irradiate light to the processing surface of the substrate W with respect to the opposite surface, thereby emitting heat energy. Preferably, a filament of the heating lamp 20a may be disposed parallel to the processing surface of the substrate W.

Also, the lamp units of the lamp part 20a may be fitted into and coupled to the opposite surface so that the filaments of the heating lamps 20a are disposed in the same direction or directions different from each other.

Thus, a portion at which the heat energy is more reduced than target heat energy by a chemical solution on a surface of the substrate W of a wafer may be reinforced within a range of heat energy emitted from the filament that is a heating source of the lamp with respect to the processing surface of the substrate W of the rotating semiconductor wafer.

Various infrared lamps such as a kanthal lamp, a halogen-tungsten lamp, and an arc lamp as lamps emitting infrared rays may be used as the heating lamp 20a. However, in the current embodiment, the halogen-tungsten lamp that emits heat energy at a temperature of 500° C. or more may be preferably used to process the substrate by using the processing solution.

The reflector 20b may be a reflection member that reflects the heat energy emitted from the heating lamp 20a toward the substrate. A curved portion having a semicircular shape may be formed around the heating lamp 20a to reflect the heat energy of the heating lamp 20a, thereby improving the heating efficiency.

The housing 20c may be a cover member installed on an outer circumferential of the heating lamp 20a. Preferably, the housing 20c may have an approximately cylindrical shape so that the heating lamp 20a and the reflector 20b are built therein.

Hereinafter, a substrate processing heater device according to a preferred second embodiment of the present invention will be described in more detail with reference to the accompanying drawings.

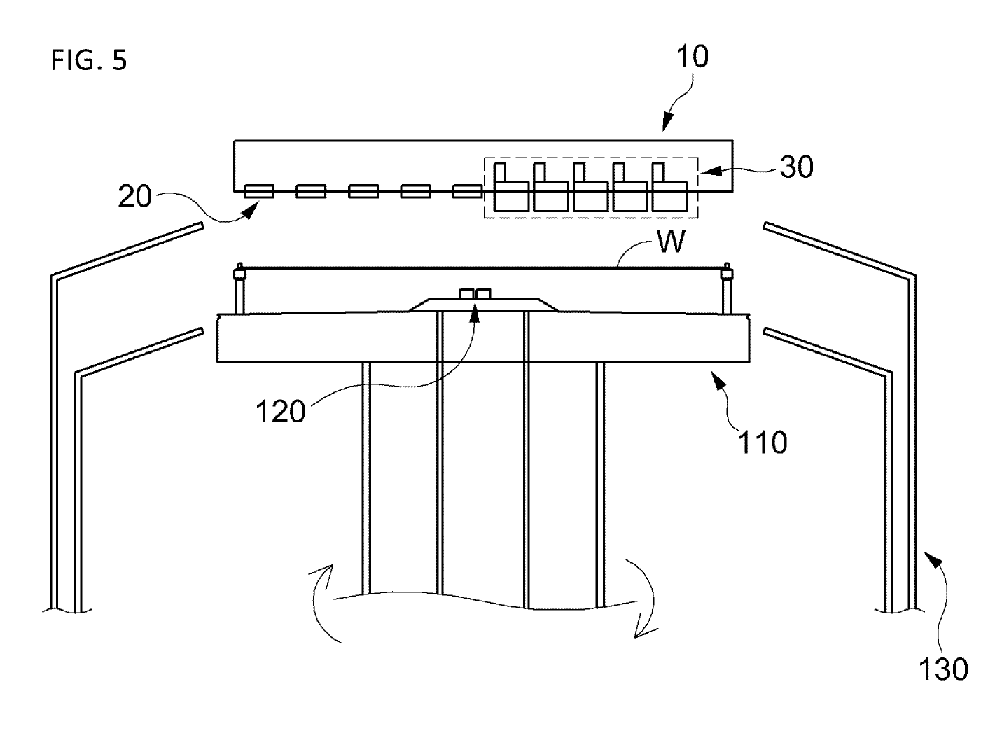

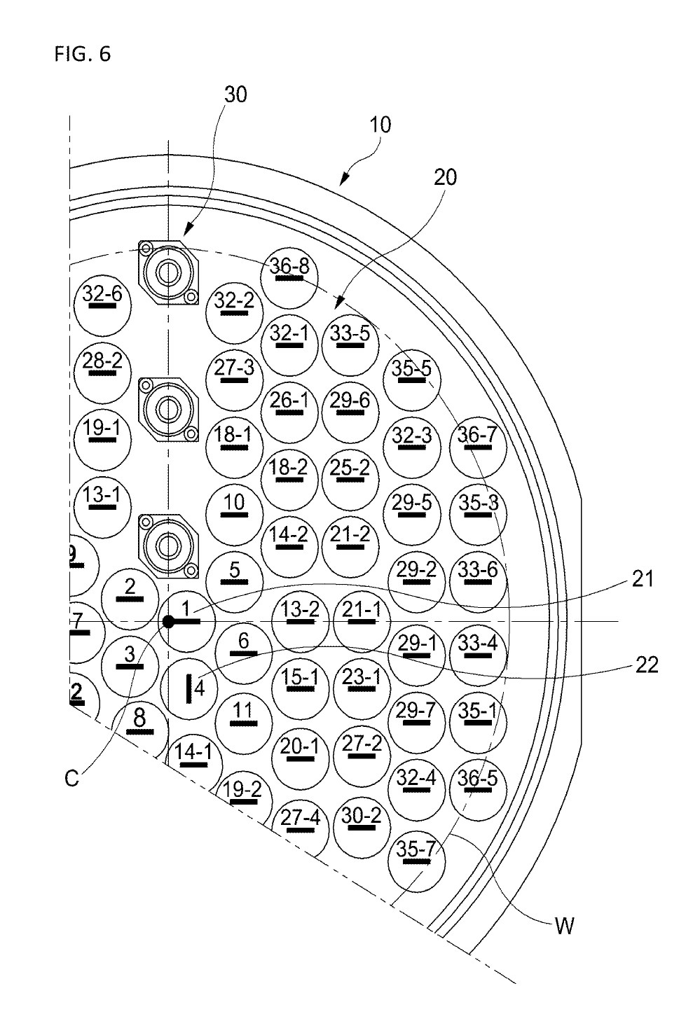

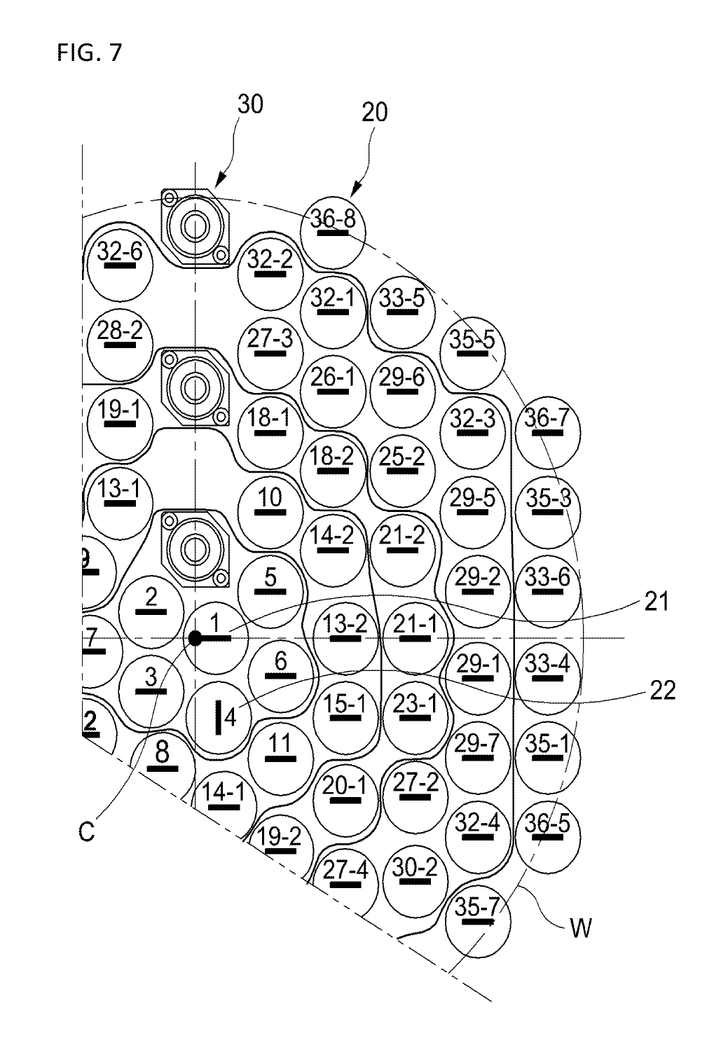

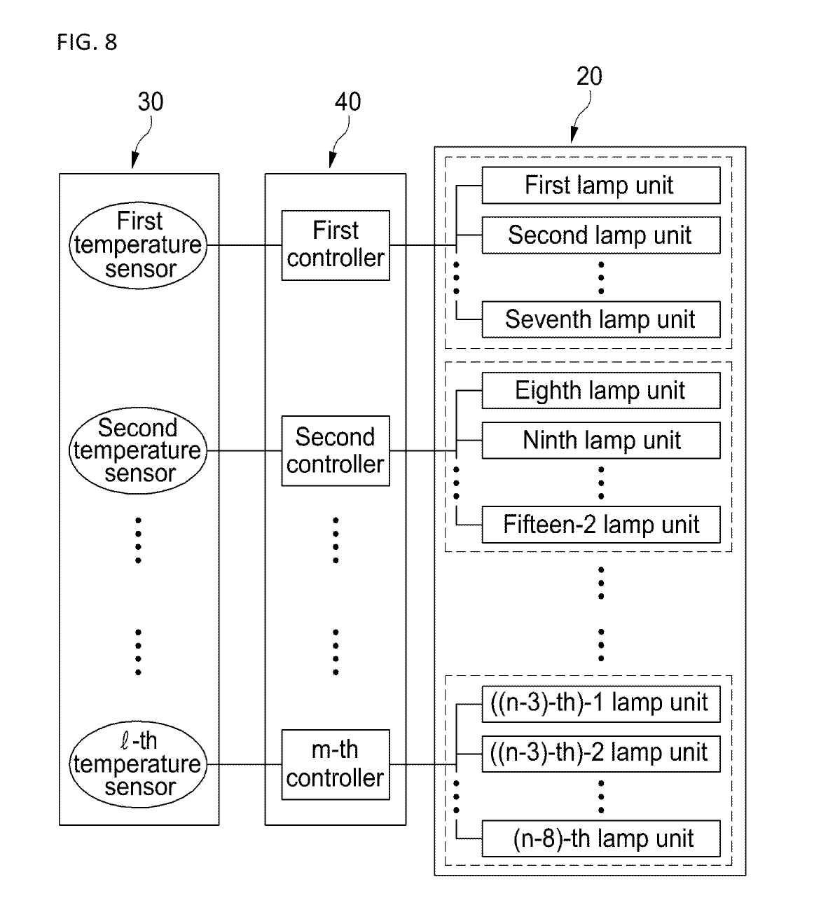

FIG. 5 is a view of a substrate solution processing device including a substrate processing heater device according to a second embodiment of the present invention, FIG. 6 is a view of the substrate processing heater device according to the second embodiment of the present invention, FIG. 7 is a view illustrating an arrangement of a control group of the substrate processing heater device according to the second embodiment of the present invention, and FIG. 8 is a block diagram illustrating a control state of the substrate processing heater device according to the second embodiment of the present invention.

Referring to FIGS. 5 and 6, a substrate processing heater device according to the second embodiment includes a heater part 10, a lamp part 20, and a temperature measurement part 30 and is a substrate processing heater device measuring a temperature of a substrate. Preferably, a circular thin plate such as a semiconductor wafer used for a semiconductor device may be used as the substrate processed in the current embodiment.

Since the heater part 10 and the lamp part 20 according to the second embodiment are the same as the heater part 10 and the lamp part 20 according to the first embodiment, the same reference numeral may be given, and their detailed descriptions will be omitted. Thus, only the temperature measurement part 30 will be described in detail.

The temperature measurement part 30 may be a measurement unit that measures a temperature of a substrate W heated by the heater part 10 in a non-contact manner. Preferably, the temperature measurement part 30 may be installed on an opposite surface of the heater part 10, which corresponds to a processing surface of the substrate W.

The temperature measurement part 30 includes at least one temperature sensor installed to measure a temperature at a position of the substrate W in a vertical direction. As illustrated in FIGS. 6 to 8, the temperature sensor may be provided in plurality such as first to 1-th temperature sensors disposed along a radius direction of the opposite surface of the heater part 10, which corresponds to the processing surface of the substrate W.

Alternatively, a plurality of temperature sensors may be disposed discrepant from each other at predetermined distances in a radius direction of the opposite surface of the heater part 10 or disposed at the same distance in the radius direction to measure a heating temperature along a circumference of the processing surface of the rotating substrate W.

Particularly, various non-contact type temperature sensors such as infrared temperature sensor, a thermopile temperature sensor, and a pyroelectric temperature sensor may be used as the non-contact type temperature sensor. However, in the current embodiment, the infrared temperature sensor such as a pyrometer that is a non-contact type infrared radiation thermometer may be used to measure a heating temperature of the substrate at a high temperature in the non-contact manner when the substrate is processed by using a processing solution.

Here, since a plurality of lamp groups in which at least one lamp unit disposed on the opposite surface constitutes one lamp group are provided, and a plurality of control groups in which the plurality of lamp groups constitute one control group are provided, the measured results of the temperature sensor may be provided by allowing the temperature sensor to be interlocked with each of the non-contact type sensors and thereby to control the intensities of the lamp units for each control group.

Particularly, the lamp groups may be provided as n lamp groups including first to (n-8)-th lamp units as illustrated in FIGS. 6 and 7. Also, as illustrated in FIGS. 7 and 8, the plurality of control groups include a first control group constituted by a plurality of lamp groups of first to seventh lamp units, a second control group constituted by a plurality of lamp groups of eighth to fifteenth-2 lamp units, and a final control group constituted by a plurality of lamp groups of a second control group to ((n-3)-th)-1 to (n-8)-th lamp units.

Thus, as illustrated in FIG. 8, the first temperature sensor measures the temperature of the substrate to provide temperature information to the first control group, and thereby to control intensities of the lamp units, the second temperature sensor measures the temperature of the substrate to provide temperature information to the second control group, and thereby to control intensities of the lamp units, and the 1-th temperature sensor measures the temperature of the substrate to provides temperature information of the final control group, and thereby to control intensities of the lamp units.

Also, the heater device according to the current embodiment may further includes a control part 40 including first to m-th controller that are respectively connected to the first to 1-th temperature sensors to control the intensities of the lamp units.

Hereinafter, a substrate solution processing device including the substrate processing heater device according to the first embodiment will be described in detail with reference to the accompanying drawings.

As illustrated in FIG. 1, the substrate solution processing device including the substrate processing heater device according to the first embodiment is a substrate solution processing device which includes a table part 110, an injection part 120, a collection part 130, a heater part 10, and a lamp part 20 and supplies a processing solution to a substrate W to process the substrate by using the processing solution.

The table part 110 is a rotation support unit that chucks and rotates a substrate W. The table part 110 may chuck and support the substrate W so that the processing surface of the substrate W faces an upper side to rotate the substrate W or chuck and support the substrate W so that the processing surface of the substrate W faces a lower side to rotate the substrate W.

Particularly, the table part 110 according to the current embodiment may chuck and support the substrate so that the processing surface of the substrate W face the lower side to allow the injection part 120 to inject the processing solution from the lower side of the substrate W.

The injection part 120 is a supply unit that injects and supplies the processing solution to the processing surface of the substrate W. When the substrate W is chucked and supported on the table part 110 so that the processing surface of the substrate W face the upper side, the injection part 120 is installed above the substrate W. When the substrate W is chucked and supported on the table part 110 so that the processing surface of the substrate W faces the lower side, the injection part 120 may be installed under the substrate W.

Preferably, the injection part 120 according to the current embodiment may inject and supply the processing solution to a lower portion of the substrate W so that the substrate W is chucked and supported on the table part 110 so as to allow the processing surface of the substrate W to face the lower side.

The collection part 130 may be a collection unit that is installed on an outer circumference of the table part 110 to collect the processing solution injected onto the substrate W. Since the processing solution injected onto the processing surface of the substrate W is discharged along the outer circumference by centrifugal force when the substrate W is rotated, the collection part 130 may have a cylindrical cup shape to collect the processing solution.

Also, the collection part 130 may have a plurality of cup shapes having a concentric circle to collect each processing solution various processing solutions when the various processing solutions are supplied to the processing surface of the substrate W.

The heater part 10 and the lamp part 20 may be heating units that heat the substrate W and constitute the substrate processing heater device according to the first embodiment. The heater part 10 and the lamp part 20 may be installed above the substrate W to heat the substrate W and the processing solution.

The heater part 10 and the lamp part 20 may be installed so that the heater part 10 is rotated above the substrate W to enter or fixed above the substrate W.

The substrate solution processing device according to the current embodiment may further include a temperature measurement part 30 that measures a heating temperature of the substrate to control an intensity of the lamp part 20.

The temperature measurement part 30 includes at least one temperature sensor installed on the opposite surface of the heater part 10. The temperature measurement part 30 measures a heating temperature for the processing surface of the substrate W to provide temperature information, thereby controlling intensities of the lamp units of the lamp part 20.

The temperature measurement part 30 includes a plurality of temperature sensors disposed discrepant from each other at predetermined distances in a radius direction of the opposite surface of the heater part 10 or disposed at the same distance in the radius direction to measure the heating temperature along a circumference of the processing surface of the substrate W rotated by the table part 110.

Also, the substrate solution processing device according to the current embodiment may further include a control part 40 that controls the intensity of the lamp part 20 for each lamp group of the lamp units.

As illustrated in FIG. 4, the control part 40 may include a plurality of controllers constituted by first to m-th controllers to control the intensity of the lamp part 20 for each lamp group of the lamp units.

Thus, the control part 40 controls the intensities of the lamp units of the lamp part 20 for each lamp group on the basis of the temperature information with respect to the processing surface of the substrate W, which is measured by the temperature measurement part 30.

Hereinafter, a substrate solution processing device including the substrate processing heater device according to the second embodiment will be described in detail with reference to the accompanying drawings.

As illustrated in FIG. 5, the substrate solution processing device including the substrate processing heater device according to the second embodiment is a substrate solution processing device which includes a table part 110, an injection part 120, a collection part 130, a heater part 10, a lamp part 20, and a substrate measurement part 30 and supplies a processing solution to a substrate W to process the substrate by using the processing solution.

Since the table part 110, the injection part 120, and the collection part 130 according to the second embodiment are the same as the table part 110, the injection part 120, and the collection part according to the first embodiment, the same reference numeral may be given, and their detailed descriptions will be omitted.

The heater part 10 and the lamp part 20 may be heating units that heat the substrate W and installed above the substrate W to heat the substrate W and the processing solution. Since the heater part 10 and the lamp part 20 according to the second embodiment are the same as the heater part 10 and the lamp part 20 according to the first embodiment, their detailed descriptions will be omitted.

Particularly, the heater part 10 may be installed so that the heater part 10 is rotated above the substrate W to enter or fixed and supported above the substrate W.

The temperature measurement part 30 may be a temperature measurement unit that measures a temperature of a substrate W heated by the heater part 10 in a non-contact manner. Since the temperature measurement part 30 is the same as the temperature measurement part 30 of the substrate processing heater device according to the second embodiment, its detailed description will be omitted.

Also, the substrate solution processing device according to the current embodiment may further include a control part 40 that controls the intensity of the lamp part 20 for each lamp group of the lamp units.

The control part 40 may include a plurality of controllers constituted by first to m-th controllers to control the intensity of the lamp part 10 for each lamp group including first to final control groups of the lamp units.

Here, a plurality of lamp groups in which at least one lamp unit disposed on the opposite surface of the heater part 10, which corresponds to the processing surface of the substrate W, constitutes one lamp group may be provided, and a plurality of control groups in which the plurality of lamp groups constitutes one control group may be provided. Thus, it is preferable that the control part 40 controls intensities of the lamp units for each control group.

Thus, the control part 40 controls the intensities of the lamp units of the lamp part 20 for each lamp group on the basis of the temperature information with respect to the processing surface of the substrate W, which is measured by the temperature measurement part 30, thereby uniformly maintaining the heating temperature of the processing surface of the substrate W.

As described above, according to the present invention, since the opposite surface of the heater part has a size greater than that of the substrate processing surface, and the plurality of lamp units are disposed adjacent to each other on the opposite surface, the heating temperature may be uniformly maintained on the substrate processing surface to prevent the substrate processing surface from being non-uniformly processed, thereby improving the substrate processing efficiency.

Also, since the opposite surface of the heater part has the same shape as the substrate processing surface, the intensity of the heater part may be concentrated into only the substrate processing surface to improve the heating efficiency of the heater part.

Also, since the reference lamp unit is eccentrically disposed with respect to the center of the opposite surface, and the peripheral lamp units are disposed to have different spaced distances from the center of the opposite surface, the lamp units may be disposed so that the heating ranges of the lamp units do not overlap each other to reduce the non-uniformity in heating temperature of the substrate processing surface.

Also, the eccentric range of the reference lamp unit may be limited to a predetermined value to prevent the heating temperature from being risen at the central portion of the substrate processing surface.

Also, since each of the lamp units is constituted by the heating lamp, the reflector, and the housing, the heat energy of the heating lamp emitting the high-temperature heat energy may be reflected toward the substrate to improve the heat energy efficiency and prevent the housing from being thermally damaged.

Also, since the filaments as the heating lamps are installed parallel to the substrate processing surface in parallel to each other, and the infrared lamp is used, the heat energy of the heating lamps may be uniformly emitted, and the lamp units may be easily maintained and repaired.

Also, since the plurality of lamp groups in which at least one lamp unit is formed as one lamp group are controlled intensity for each lamp group, the intensities of the lamp units disposed on the opposite surface may be controlled for each area.

Also, since one lamp unit is formed as one lamp group at the central portion of the substrate, and the plurality lamp units are formed as one lamp group at the outer portion, the intensities of the lamp units may be variously controlled at the central portion and the outer portion of the substrate processing surface to reduce the deviation in heating temperature for each area of the substrate processing surface.

Also, since the heater device is installed above the substrate, and the injection part is installed under the substrate in the substrate solution processing device, when the substrate is processed by using the processing solution, the contamination of the heater device may be prevented, and the solution processing efficiency may be improved.

Also, since the temperature measurement part and the control part are provided in the substrate solution processing device, the heating temperature with respect to the substrate processing surface may be more accurately controlled for each lamp group of the lamp units.

Also, since the temperature measurement part is installed so that the temperature of the substrate heated by the heating unit is measured in a non-contact manner, the portion at which the heating temperature on the substrate processing surface is non-uniform may be measured to provide the heating temperature information so that the heating temperature of the substrate is uniformly maintained, thereby improving the substrate processing efficiency.

Also, since the temperature measurement part is installed on the opposite surface of the heater part, the temperature measurement part may be fixedly installed on the heater part so as to be moved or fixed together with the heater part to simplify a mechanical constitution without installing a separate moving unit or fixing unit for a temperature measurement part.

Also, since the temperature measurement part is provided as at least one temperature sensor installed to measure the temperature at a position of the substrate in the vertical direction with respect to the substrate processing surface, the distance between the temperature measurement part and the substrate processing surface may be parallely maintained to improve the accuracy in temperature measurement of the temperature sensor.

Also, since the plurality of temperature sensors are disposed on the opposite surface of the heater part in the radius direction, the temperature of the substrate processing surface rotated when the substrate is processed may be measured along the circumferential direction to easily measure the temperature of the entire substrate processing surface.

Also, since the intensities of the lamp units are controlled for each control group by the measured result of the temperature sensor of the temperature measurement part, the intensity of the heater part with respect to the lamp units may be controlled to be uniformly maintained on the substrate processing surface.

Also, since the opposite surface of the heater part has the same shape as the substrate processing surface, the intensity of the heater part may be concentrated into only the substrate processing surface to improve the heating efficiency of the heater part.

Also, since the filaments as the heating lamps are installed parallel to the substrate processing surface in the same direction, the heat energy of the heating lamps may be uniformly emitted, and the lamp units may be easily maintained and repaired.

Also, since the reference lamp unit is eccentrically disposed with respect to the center of the opposite surface, and the peripheral lamp units are disposed to have the same spaced distance or different spaced distances from the center of the opposite surface, the lamp units may be disposed so that the heating ranges of the lamp units do not overlap each other to reduce the non-uniformity in heating temperature of the substrate processing surface.

Also, since the heater device is installed above the substrate, and the injection part is installed under the substrate in the substrate solution processing device, when the substrate is processed by using the processing solution, the contamination of the heater device may be prevented, and the solution processing efficiency may be improved.

Also, since the temperature measurement part and the control part are provided in the substrate solution processing device, the heating temperature with respect to the substrate processing surface may be more accurately controlled for each lamp group of the lamp units.

The foregoing present invention may be carried out in various embodiments without departing from the technical ideas or primary features. Therefore, the above-described embodiments are merely illustrative of the present invention, but should not be limitedly interpreted.

### INDUSTRIAL APPLICABILITY

The present invention provides a substrate processing heater device that heats a substrate and measures a temperature of the substrate to process the substrate and a substrate solution processing device.

1. A substrate processing heater device, which heats a substrate to process the substrate, comprising:
a heater part heating the substrate; and
a lamp part comprising a plurality of lamp units disposed adjacent to each other on the heater part.

2. The substrate processing heater device of claim 1, wherein the heater part has an opposite surface having a size greater than that of a processing surface of the substrate.

3. The substrate processing heater device of claim 2, wherein the opposite surface has the same shape as the processing surface of the substrate.

4. The substrate processing heater device of claim 1, wherein the lamp part comprises:
a reference lamp unit eccentrically disposed with respect to a center of the opposite surface, which corresponds to a center of the processing surface of the substrate; and
a plurality of peripheral lamp units disposed at the same spaced distance from a center of the opposite surface or difference spaced distances from the center of the opposite surface by using the reference lamp unit as a center.

5. The substrate processing heater device of claim 4, wherein an eccentric range of the reference lamp unit is within ⅔ of a diameter of each of the lamp units.

6. The substrate processing heater device of claim 1, wherein each of the lamp units comprises:
a heating lamp emitting heat energy toward the substrate;
a reflector reflecting the heat energy of the heating lamp to the substrate; and
a housing installed on an outer circumference of the heating lamp.

7. The substrate processing heater device of claim 6, wherein the heating lamp comprises a filament disposed parallel to the processing surface of the substrate.

8. The substrate processing heater device of claim 7, wherein the lamp unit is coupled to be fitted so that the filaments of the heating lamps are disposed in the same direction as each other or directions different from each other.

9. The substrate processing heater device of claim 6, wherein the heating lamp comprises an infrared lamp.

10. The substrate processing heater device of claim 1, wherein the lamp part comprises a plurality of lamp groups in which at least one lamp unit constitutes one lamp group, and intensities of the lamp units are controlled from each lamp group.

11. The substrate processing heater device of claim 10, wherein one lamp unit constitutes one lamp group at a central portion of the lamp part, and a plurality of lamp units constitute one lamp group at an outer portion of the lamp part.

12. The substrate processing heater device of claim 1, further comprising a temperature measurement part that measures a temperature of the substrate heated by the heater part in a non-contact manner.

13. The substrate processing heater device of claim 12, wherein the temperature measurement part is installed on the opposite surface of the heater part, which corresponds to the processing surface of the substrate.

14. The substrate processing heater device of claim 12, wherein the temperature measurement part comprises at least one temperature sensor installed to measure the temperature at a position of the substrate in a vertical direction.

15. The substrate processing heater device of claim 14, wherein the temperature sensor is provided in plurality along a radius of the opposite surface of the heater part corresponding to the processing surface of the substrate.

16. The substrate processing heater device of claim 14, wherein, since a plurality of lamp groups in which at least one lamp unit disposed on the opposite surface constitutes one lamp group are provided, and a plurality of control groups in which the plurality of lamp groups constitute one control group are provided, measured results of the temperature sensor are provided by allowing the temperature sensor to be interlocked with each of the non-contact type sensors and thereby to control intensities of the lamp units for each control group.

17. The substrate processing heater device of claim 14, wherein the temperature sensor comprises a non-contact type infrared radiation thermometer.

18. A substrate solution processing device, which supplies a processing solution to a substrate to process the substrate by using the processing solution, comprising:
a table part chucking and rotating the substrate;
an injection part injecting the processing solution onto the substrate;
a collection part collecting the processing solution injected onto the substrate;
a heater part heating the substrate; and
a lamp part comprising a plurality of lamp units disposed adjacent to each other on the heater part.

19. The substrate solution processing device of claim 18, wherein the heater part has an opposite surface having a size greater than that of a processing surface of the substrate.

20. The substrate solution processing device of claim 18, wherein the table part chucks the substrate to allow the processing surface of the substrate to face an upper side,
the injection part is installed above the substrate to inject the processing solution onto the processing surface of the substrate, and
the heater part is installed above the substrate to heat the substrate and the processing solution.

21. The substrate solution processing device of claim 18, wherein the table part chucks the substrate to allow the processing surface of the substrate to face a lower side,
the injection part is installed below the substrate to inject the processing solution onto the processing surface of the substrate, and
the heater part is installed above the substrate to heat the substrate and the processing solution.

22. The substrate solution processing device of claim 18, further comprising a temperature measurement part that measures a heating temperature of the substrate to control an intensity of the lamp part.

23. The substrate solution processing device of claim 22, wherein the temperature measurement part measures a temperature of the substrate heated by the heater part in a non-contact manner.

24. The substrate solution processing device of claim 18, further comprising a control part that controls an intensity of the lamp part for each lamp group of the lamp units.

25. The substrate solution processing device of claim 24, wherein, since a plurality of lamp groups in which at least one lamp unit disposed on the opposite surface corresponding to the processing surface of the substrate constitutes one lamp group are provided, and a plurality of control groups in which the plurality of lamp groups constitute one control group are provided, the control part is interlocked with each of the non-contact type sensors to control intensities of the lamp units for each control group.
